(19) United States
(12) Patent Application Publication
(10) Pub. No.: US 2002/0182870 A1
(43) Pub. Date: Dec. 5, 2002

(54) Substrate processing apparatus and a method for fabricating a semiconductor device by using same

(75) Inventors: Tatsuhisa Matsunaga, Tokyo (JP); Akihiro Sato, Tokyo (JP); Norio Akutsu, Tokyo (JP)

Correspondence Address: BACON & THOMAS, PLLC, 625 SLATERS LANE, FOURTH FLOOR, ALEXANDRIA, VA, 22314

(73) Assignee: Hitachi Kokusai Electric Inc., Tokyo (JP)

(21) Appl. No.: 10/106,375

(22) Filed: Mar. 27, 2002

(30) Foreign Application Priority Data
May 30, 2001 (JP) 2001-162802

(51) Int. Cl. H01L 21/311

(52) U.S. Cl. 438/700

(57) ABSTRACT

A substrate processing apparatus includes a process tube, which processes a plurality of wafers held in a boat and a load lock chamber accommodating therein the boat before and after the boat is loaded into and unloaded from the process tube. The load lock chamber is raised and lowered along with the process tube disposed thereon by a boat elevator and a moving stroke of the load lock chamber is set to be greater than a length of the process tube.

### FIELD OF THE INVENTION

The present invention relates to a substrate processing method and apparatus to be used in fabricating a semiconductor device; and, more particularly, to a substrate processing method and an apparatus therefor having a loadlock chamber and, e.g., being suitable for diffusing impurities or forming a CVD layer, such as an insulating or a metal layer on a semiconductor wafer having thereon an integrated circuit including semiconductor devices.

### BACKGROUND OF THE INVENTION

In U.S. Pat. No. 5,571,330, there is disclosed a vertical type heat treatment apparatus being used as a conventional substrate processing apparatus for diffusing impurity or forming a CVD layer on a wafer. The vertical type heat treatment apparatus includes a treatment chamber having an opening formed thereunder, through which a boat holding a plurality of wafers is loaded into and unloaded from the treatment chamber. The opening is closed when the boat is completely inserted in the treatment chamber. A vertically extendable/contractible load lock chamber is provided under the treatment chamber. The load lock chamber is formed with two metallic bellows with differing size constituting vertically disposed upper and lower chamber portions and a connecting member for connecting chamber portions. The connecting member is constructed such that the two chamber portions are telescopically nested into the connecting member when they are fully contracted.

An upper end of the bellows forming the upper chamber portion is airtightly connected to the treatment chamber and a lower end of the bellows forming the lower chamber portion is airtightly closed by a boat stage. Both chamber portions configure to be extended or contracted by an elevator structure disposed outside the load lock chamber and coupled with the connecting member and the boat stage.

The above-mentioned load lock chamber for the vertical type heat treatment apparatus, however, has a critical deficiency. If the vertical type heat treatment apparatus processes a wafer having a diameter of 300 mm, the diameters of the first and the second bellows need to be larger than 400 mm and 500 mm both inclusive, respectively. In that case, whenever the first and the second bellows are in a vacuum state, forces of about 2000 kgf (about 20000 N) and 1200 kgf (about 12000 N), respectively, act on the first and the second bellows because of a pressure difference between the atmospheric pressure (1 kgf/cm², or about 98 kPa) and the vacuum pressure of each bellows. As a result, when the wafer processed by the vertical type heat treatment apparatus has the diameter of 300 mm, a very large-sized drive mechanism should be employed to drive a vertically extending/contracting mechanism of the load lock chamber.

Further, the boat and a process tube of the treatment chamber are exposed to a process gas with which the boat and the process tube can react and a resultant reaction product thereof is formed on the surface thereof, so that the boat and the reaction tube need to be removed from the heat treatment apparatus and cleaned in order to remove the reaction product therefrom regularly.

However, in the conventional heat treatment apparatus, the treatment chamber and the load lock chamber must be disassembled to extract the reaction tube and the boat therefrom.

### SUMMARY OF THE INVENTION

It is, therefore, an object of the present invention to provide a substrate processing apparatus from which a process tube and a boat can be easily extracted without requiring a bulky boat elevator.

In accordance with one aspect of the invention, there is provided a substrate processing apparatus, which comprises: a process tube, which processes a plurality of wafers held in a boat; and a load lock chamber accommodating therein the boat before and after the boat is loaded into and unloaded from the process tube, wherein the load lock chamber is raised and lowered along with the process tube disposed thereon.

In accordance with another aspect of the invention, there is provided a substrate processing apparatus, which comprises; a process tube, which processes a plurality of wafers held in a boat; a load lock chamber accommodating therein the boat before and after the boat is loaded into and unloaded from the process tube; a boat elevator, installed outside the load lock chamber, for raising and lowering a lift arm assembly; a support column vertically disposed on the lift arm assembly and passing through an opening formed in a bottom wall of the load lock chamber; a sealing cap, attached to an upper end of the support column, for sealing an opening of the process tube, the boat being disposed on the sealing cap; and a bellows surrounding the support column, one end of the bellows being airtightly attached to a periphery of the opening formed in the bottom wall of the load lock chamber and the other end of the bellows being airtightly attached to the lift arm assembly.

In accordance with still another aspect of the invention, there is provided a substrate processing apparatus, which comprises; a process tube, which processes a plurality of wafers held in a boat; a load lock chamber accommodating therein the boat before and after the boat is loaded into and unloaded from the process tube; a boat elevator, installed outside the load lock chamber, for raising and lowering a lift arm assembly; a support column vertically disposed on the lift arm assembly and passing through an opening formed in a bottom wall of the load lock chamber; a sealing cap, attached to an upper end of the support column, for sealing an opening of the process tube, the boat being disposed on the sealing cap; and a bellows surrounding the support column, one end of the bellows being airtightly attached to a periphery of the opening formed in the bottom wall of the load lock chamber and the other end of the bellows being airtightly attached to the sealing cap.

In accordance with still another aspect of the invention, there is provided a method for fabricating semiconductor devices by using a substrate processing apparatus having: a process tube, which processes a plurality of wafers held in a boat; and a load lock chamber accommodating therein the boat before and after the boat is loaded into and unloaded from the process tube, wherein the load lock chamber is raised and lowered along with the process tube disposed thereon.

### BRIEF DESCRIPTION OF THE DRAWINGS

The above and other objects and features of the present invention will become apparent from the following description of preferred embodiment given in conjunction with the accompanying drawings, in which:

FIG. 1A shows a top view of the batch-type CVD apparatus in accordance with a first preferred embodiment;

FIG. 1B describes a horizontal cross-sectional view of the batch-type CVD apparatus in accordance with the first preferred embodiment;

FIG. 2 illustrates a vertical cross-sectional view of the batch-type CVD apparatus of FIGS. 1A and 1B for explaining a wafer charging process;

FIG. 3 offers a vertical cross-sectional view of the batch-type CVD apparatus of FIGS. 1A and 1B for explaining a process of forming a layer;

FIG. 4 presents a partial cross sectional view of the batch-type CVD apparatus of FIGS. 1A and 1B for explaining a process of carrying a boat out of a load lock chamber;

FIG. 5 represents a partial cross sectional view of the batch-type CVD apparatus of FIGS. 1A and 1B for explaining an initial stage of a process of transferring a process tube out of a heater unit;

FIG. 6 sets forth a partial cross sectional view of the batch-type CVD apparatus of FIGS. 1A and 1B for explaining a final stage of the process of transferring the process tube out of the heater unit;

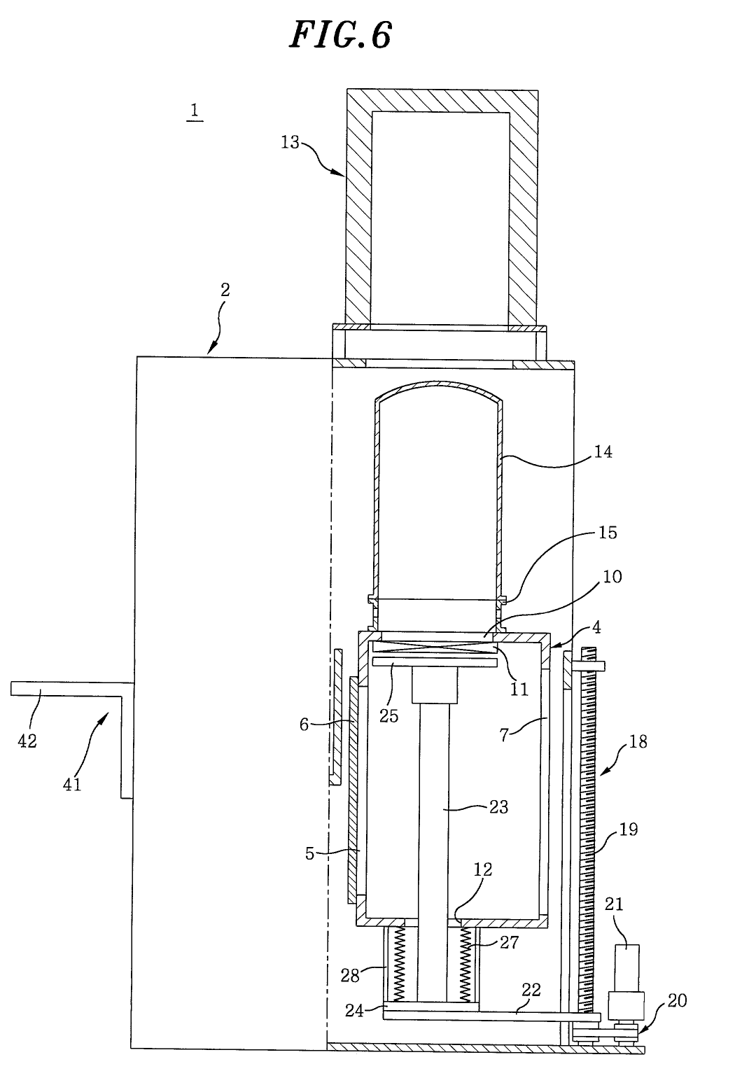

FIG. 7 shows a vertical cross sectional view of a batch-type CVD apparatus in accordance with a second preferred embodiment of the present invention;

FIG. 8 illustrates a vertical cross-sectional view of the batch-type CVD apparatus of FIG. 7 for explaining a process of forming a layer;

FIG. 9 describes a partial cross sectional view of the batch-type CVD apparatus of FIG. 7 for explaining a process of carrying a boat out of a load lock chamber;

FIG. 10 offers a partial cross sectional view of the batch-type CVD apparatus of FIG. 7 for explaining an initial stage of a process of transferring a process tube out of a heater unit;

FIG. 11 provides a partial cross sectional view of the batch-type CVD apparatus of FIG. 7 for explaining a final stage of the process of transferring the process tube out of the heater unit;

FIG. 12 presents a vertical cross sectional view of the batch-type CVD apparatus in accordance with a third preferred embodiment of the present invention;

FIG. 13 illustrates a vertical cross-sectional view of the batch-type CVD apparatus of FIG. 12 for explaining a process of forming a layer; and

FIG. 14 describes a partial cross sectional view of the batch-type CVD apparatus of FIG. 12 for explaining a process of carrying a process tube out of a load lock chamber.

### DETAILED DESCRIPTION OF THE PREFERRED EMBODIMENTS

Preferred embodiments of the present invention will now be described with reference to the accompanying drawings.

A substrate processing apparatus in accordance with the preferred embodiments of the present invention is a batch-type vertical apparatus for performing a diffusion or a CVD process (referred to as a batch-type CVD apparatus hereinafter), which is used to diffuse impurities or form a CVD layer such as an insulating layer and a metal layer on the surface of the wafer during a semiconductor fabrication process. In addition, the batch-type CVD apparatus 1 uses a FOUP (front opening unified pod, referred to as a pod hereinafter) as a wafer carrier.

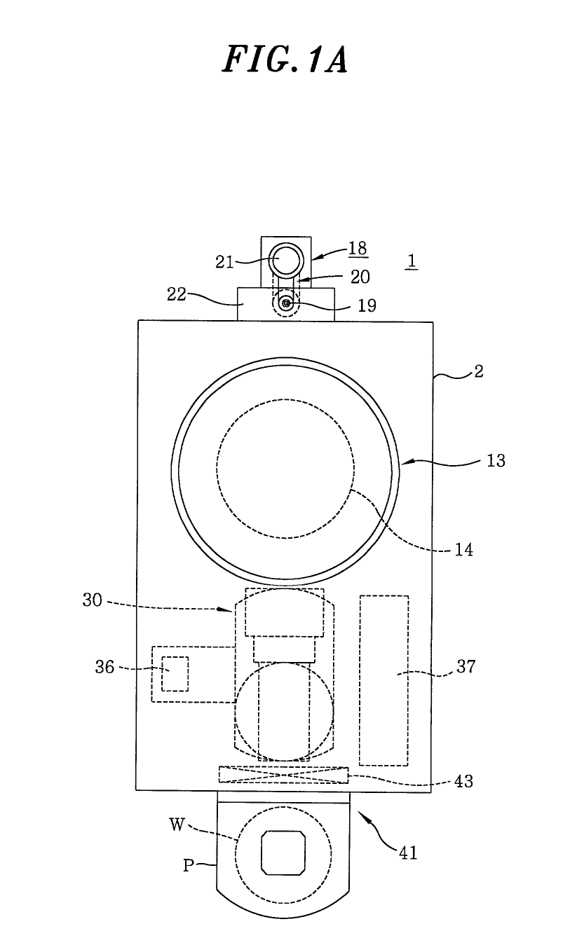

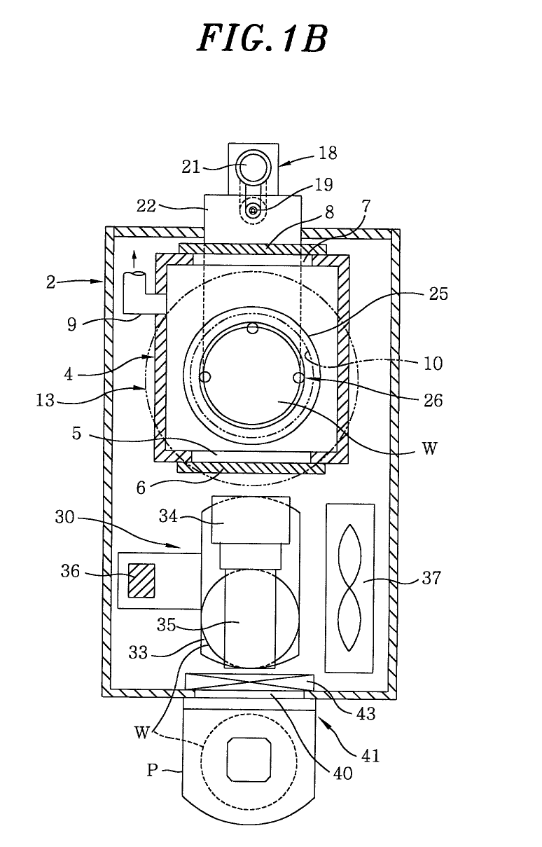

In the following description, a front, a rear, a left and a right side are defined with reference to FIG. 1, wherein the front side refers to where a pod opener 41 is located; the rear side refers to where a load-lock chamber 4 is located; the left side refers to where an elevator 36 of a wafer transfer device 30 is located; and the right side refers to where a clean unit 37 is located.

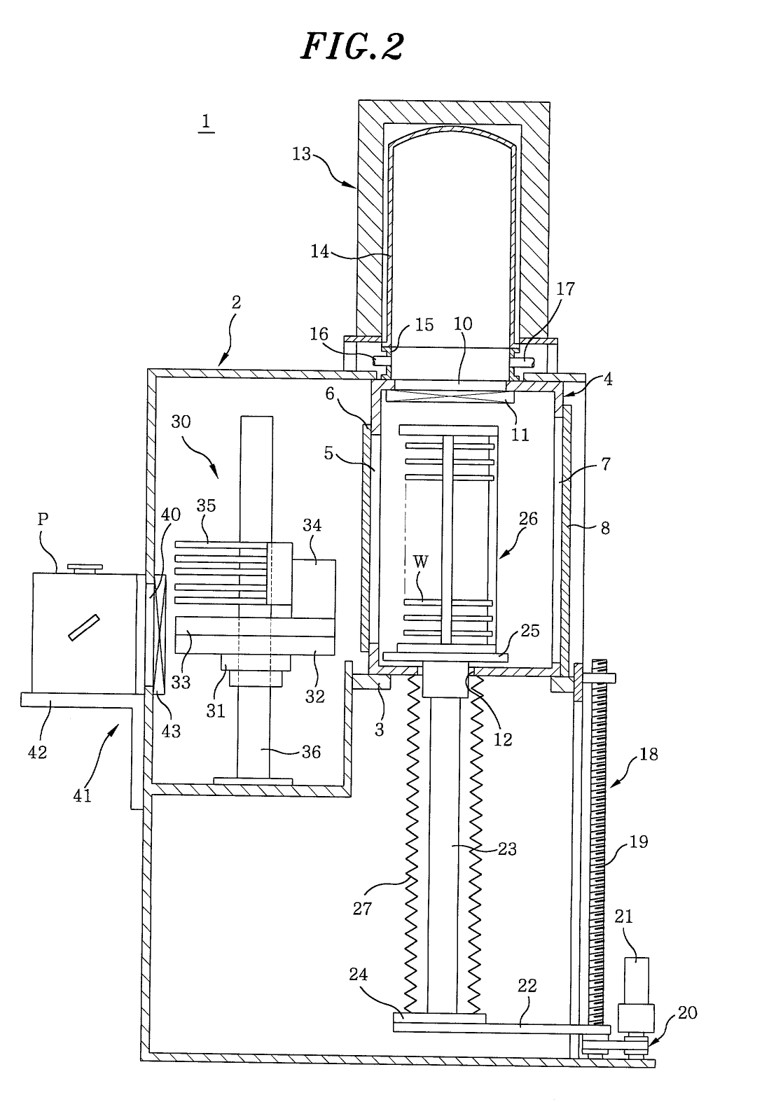

As shown in FIGS. 1A to 3, the batch-type CVD apparatus 1 includes a housing 2 and the load lock chamber 4 disposed in a rear portion of the housing 2 and forming an airtight chamber for accommodating a boat 26 therein. The load lock chamber 4 configures to be raised and lowered in the housing 2 when necessary. However, it is fixedly mounted in an upper rear portion of the housing 2 by a fixture 3 during a normal operation process as shown in FIGS. 2 to 4. There is a wafer transfer opening 5 formed in a front wall of the load lock chamber 4, through which wafers W are transferred from and into the boat 26. The wafer transfer opening 5 is opened or closed by a gate 6. Formed at a rear wall of the load lock chamber 4 is a maintenance opening 7, through which the boat 26 is carried out of and into the load lock chamber 4 during the maintenance stage. The maintenance opening 7 is closed with the gate 8. As shown in FIG. 1B, the load lock chamber 4 is provided with an exhaust line 9 which serves to control and maintain the inner pressure of the load lock chamber 4 at a certain level.

The load lock chamber 4 has a boat opening 10 formed in its top wall, through which the boat 26 is loaded in or unloaded from a process tube 14. The boat opening 10 is opened or closed by a gate 11. In addition, the load lock chamber 4 has a support opening 12 formed in a bottom wall, through which a support column 23 passes. The opening 12 is designed in such a manner that its center is substantially aligned with that of the boat opening 10.

On a rear portion of the housing 2, a heater unit 13 is vertically installed and the process tube 14 having a closed upper end and an open lower end is concentrically disposed in the heater unit 13. The process tube 14 is supported by a manifold 15 disposed on the top wall of the load lock chamber 4, wherein the manifold 15 is provided with a gas supply line 16 for supplying a source gas or a purge gas into the process tube 14 and an exhaust line 17 for evacuating an inner space of the process tube 14. The manifold 15 is disposed in such a manner that its axial line is substantially passing through the center of the boat opening 10. The axial line of the process tube 14 is substantially aligned with those of the manifold 15 and the load lock chamber 4.

Outside a lower rear portion of the housing 2, a boat elevator 18 is disposed for raising and lowering the boat 26 or the load lock chamber 4, as will be described later. The boat elevator 18 has a feed screw 19 vertically and rotatably disposed at a lower portion of the batch-type CVD apparatus 1 outside a rear wall of the housing 2, a motor 21 for rotating the feed screw 19 clockwise or counterclockwise through a transmission device 20 for conveying the rotation of the motor 21 to the feed screw 19. The boat elevator 18 is further provided with a lift arm 22 which is screw connected to the feed screw 19 in such a manner that it can be raised and lowered by the rotation of the feed screw 19 and the support column 23 which is vertically disposed on an end of the lift arm 22 so that it can move up or down along with the lift arm 22, wherein the connection between the support column 23 and the lift arm 22 is reinforced by a flange 24 disposed between the end of the lift arm 22 and the support column 23. A stroke of the lift arm 22 is greater than the height of the process tube 14. Further, it is preferable to use a ball screw mechanism for the connection between the feed screw 19 and the lift arm 22 in order to confer a smooth operation to the boat elevator 18 without increasing backlash.

The upper portion of the support column 23 is inserted in the load lock chamber 4 by passing through the support opening 12 and has a sealing cap 25 horizontally disposed thereat. The sealing cap 25 is configured to airtightly seal the boat opening 10 functioning as a furnace mouth and support the boat 26 uprightly. The boat 26 holding a plural number, e.g., 25, 50, 100, 125 or 150, of wafers W horizontally disposed therein with their centers vertically aligned is loaded into or unloaded from the process tube 14 in accordance with the ascent or descent motion of the sealing cap 25 made by the boat elevator 18. The axial line of the support column 23 is substantially aligned with the axial lines of the process tube 14, manifold 15 and the load lock chamber 4.

A bellows 27 made of a metal, e.g., stainless metal, and having a shape of a corrugated cylinder surrounds the support column 23 concentrically, wherein an upper end of the bellows 27 is airtightly attached around a periphery of the opening 12 of the load lock chamber 4 and a lower end of the bellows 27 is also airtightly attached to the flange 24. The inner diameter of the bellows 27 is substantially same as the diameter of the support opening 12 and is extendable or contractible so that the bellows 27 allows the support column 23 to ascend and descend while the opening 12 of the load lock chamber 4 is hermetically sealed.

As shown in FIGS. 1A to 3, a wafer transfer device 30 for transferring the wafers W into or from the boat 26 is installed in the front portion of the housing 2. The wafer transfer device 30 has a rotary actuator 31 and a first linear actuator 32 disposed on the rotary actuator 31, wherein the rotary actuator 31 is configured to rotate the first linear actuator 32 in a horizontal plane. On an upper surface of the first linear actuator 32, a second linear actuator 33 is disposed, wherein the first linear actuator 32 is designed to move the second linear actuator 33 horizontally. A movable block 34 is installed on an upper surface of the second linear actuator 33 configured to move it horizontally. The movable block 34 has plural pairs of tweezers 35 (in this example, five pairs of tweezers) horizontally disposed with a same vertical distance therebetween. The wafer transfer device 30 configures to be raised or lowered by the elevator 36 having, e.g., a feed screw mechanism. On an opposite side to the elevator 36, the clean unit 37 is located for supplying clean air to the inner space of the housing 2 is located.

As shown in FIGS. 1A to 3, a wafer loading/unloading opening 40, through which wafers can be loaded into or unloaded from the housing 2, is formed in the front wall of the housing 2. Installed at the wafer loading/unloading opening 40 is the pod opener 41, which includes a loading port 42 on which a pod P is loaded and a pod cap removing/restoring device 43 for opening or restoring a cap of the pod P placed on the loading port 42. The pod opener 41 is configured such that the pod P is loaded on or unloaded from the loading port 42 by a pod transport system (not shown) such as a rail-guided vehicle (RGV).

A film forming process in a semiconductor device fabrication method by using the batch-type CVD apparatus 1 will now be described.

As shown in FIGS. 1 and 2, the pod P containing a plurality of wafers W is moved to the batch-type CVD apparatus 1 for performing the step of forming layers and then is loaded on the loading port 42 of the pod opener 41 by the pod transport system. The cap of the pod P is opened with the pod door removing/restoring device 43 so that the wafer loading/unloading opening 40 is cleared.

After the cap of the pod P is opened by the pod opener 41, the wafers W contained in the pod P are picked up by, e.g., five wafers at a time and transferred into the housing 2 through the wafer loading/unloading opening 40 by the tweezers 35 of the wafer transfer device 30 installed in the housing 2. After five wafers W held by the tweezers 35 are transferred into the housing 2 by the wafer transfer device 30, the wafer transfer opening 5 of the load lock chamber 4 is uncovered by opening the gate 6. Then, five wafers W held by the tweezers 35 are transferred into the boat 26 through the wafer transfer opening 5 of the load lock chamber 4 by the wafer transfer device 30.

The wafer transferring process described above is repeated until a desired number of wafers are charged into the boat 26. The boat opening 10 is closed by the gate 11 during the wafer transferring process, so that a high-temperature ambience employed in the process tube 14 is prevented from being introduced into the inner space of the load lock chamber 4. Accordingly, the wafers W having been loaded in and being transferred to be loaded into the boat 26 are not exposed to the high-temperature ambience, so that an adverse effect caused by the exposure to the high-temperature ambience, e.g., natural oxidation of the wafers, can be prevented.

As shown in FIGS. 1A to 2, the wafer transfer opening 5 is closed by the gate 6 after a predetermined number of the wafers are loaded in the boat 26. In addition, the maintenance opening 7 and the boat opening 10 are closed by the gates 8 and 11, respectively. Then, the inner space of the load lock chamber 4 held in such load-locked state is evacuated through the exhaust line 9 to remove oxygen and moisture contained therein.

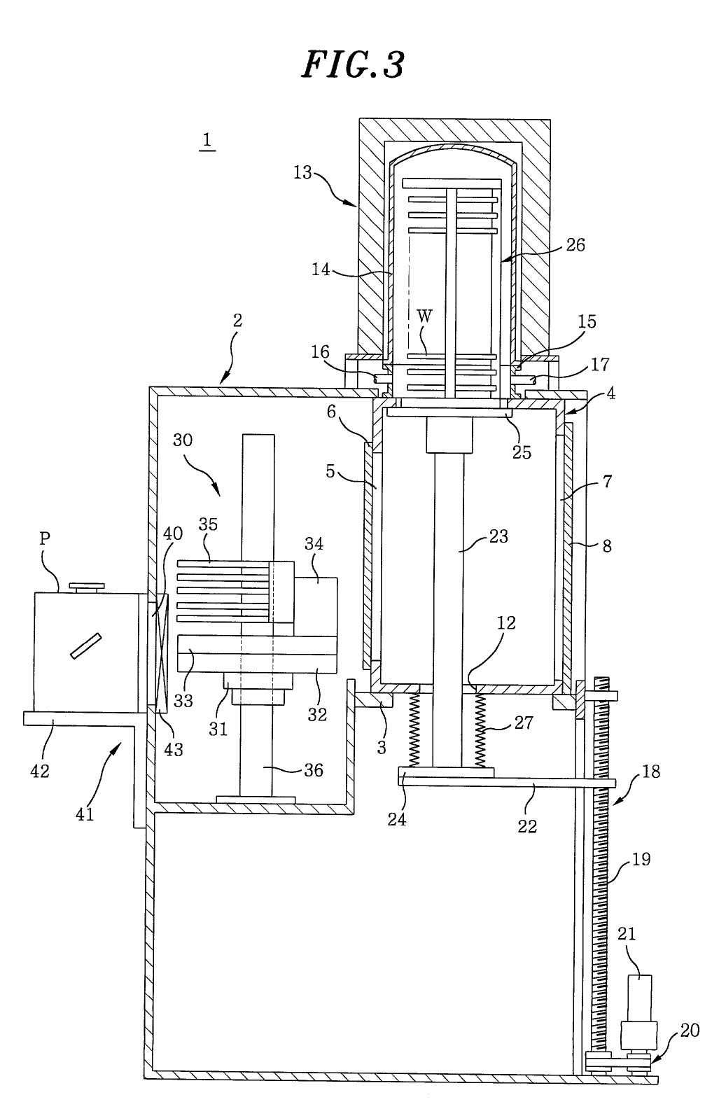

After the oxygen and moisture removal process is carried out by evacuating the load lock chamber 4, the boat opening 10 is opened by the gate 11 and then the boat 26 is raised by the support column 23 of the boat elevator 18 to be loaded into the process tube 14 as shown in FIG. 3. When the boat is raised to the its uppermost position, an upper periphery of the sealing cap 25 supporting the boat 26 comes into airtight contact with the periphery of the boat opening 10. Accordingly, the process tube 14 is airtightly closed.

Since the oxygen and the moisture in the load lock chamber 4 are removed before the boat opening 10 is uncovered in order to load the boat 26 in the process tube 14, the oxygen and the moisture are effectively prevented from being introduced into the process tube 14. In addition, since the inner space of the bellows 27 is also evacuated through the support opening 12, oxygen and moisture in the inner space of the bellows 27 are also removed. Accordingly, even though the bellows 27 is contracted while the support column 23 is raised to load the boat 26 into the process tube 14, the oxygen and the moisture in the inner space of the bellows 27 are also prevented from being introduced into the process tube 14.

Next, the inner space of the process tube 14 airtightly closed is evacuated to a predetermined pressure through the exhaust line 17 and then, heated to a predetermined temperature. After that, a source gas is introduced into the process tube 14 through the gas supply line 16 at a predetermined flow rate to form a layer on the wafers W under a predetermined process condition.

After a predetermined period of time being elapsed, the boat 26 holding processed wafers W is lowered by the boat elevator 18 as shown in FIG. 2, so that the boat 26 is unloaded into the load lock chamber 4. When the boat 26 is unloaded from the process tube 14, the bellows 27 is vertically extended since the support column 23 is lowered. In the batch-type CVD apparatus 1 in accordance with a first preferred embodiment of the present invention, the inner space of the bellows 27 communicates with that of the load lock chamber 4 through the support opening, so that inner pressures in both spaces are same. Therefore, the bellows 27 can be extended normally.

After the boat 26 is unloaded into the load lock chamber 4, the boat opening 10 is closed by the gate 11 and then the load-locked state is released by opening the wafer transfer opening 5 of the load lock chamber 4 by the gate 6 and the processed wafers W held in the boat 26 are unloaded from the boat 26 by the wafer transfer device 30. The cap of the empty pod P and the wafer loading/unloading opening 40 are opened by the pod cap removing/restoring device 43. Then, the processed wafers W are transferred into the empty pod P through the wafer loading/unloading opening 40 by the wafer transfer device 30.

After the predetermined number of the processed wafers W are loaded in the empty pod P, the cap of the pod P is restored by the pod cap removing/restoring device 43. Then, the pod P is transferred from the loading port 42 for a next process by the pod transport system. The step of transferring the processed wafers W from the boat 26 to the empty pod P mounted on the loading port 42 is repeated until all the processed wafers W held in the boat 26 are transferred to the pods P.

The steps described above are repeated, so that a predetermined number of, e.g., 25, 50, 100, 125 or 150, wafers W are batch-processed by the batch-type CVD apparatus 1. While the batch process being performed, the load lock chamber 4 maintains the fixedly mounted state at the upper portion of the housing 2 by means of the fixture 3.

The repetition of the batch processes described above entails contamination of the inner surface of the process tube 14 and the surface of the boat 26 due to the formation of accumulated layers thereon and the attachment of particulates thereto. The accumulated layers and the particulates may be peeled off from the process tube 14 and the boat 26 to cause a decrease in the production yield of the semiconductor devices. Accordingly, the maintenance, e.g., cleaning, of the process tube 14 and the boat 26 must be carried out on a regular or irregular basis.

A criticality of the semiconductor device manufacturing method in accordance with the preferred embodiment of the present invention, i.e., a maintenance process, will now be described.

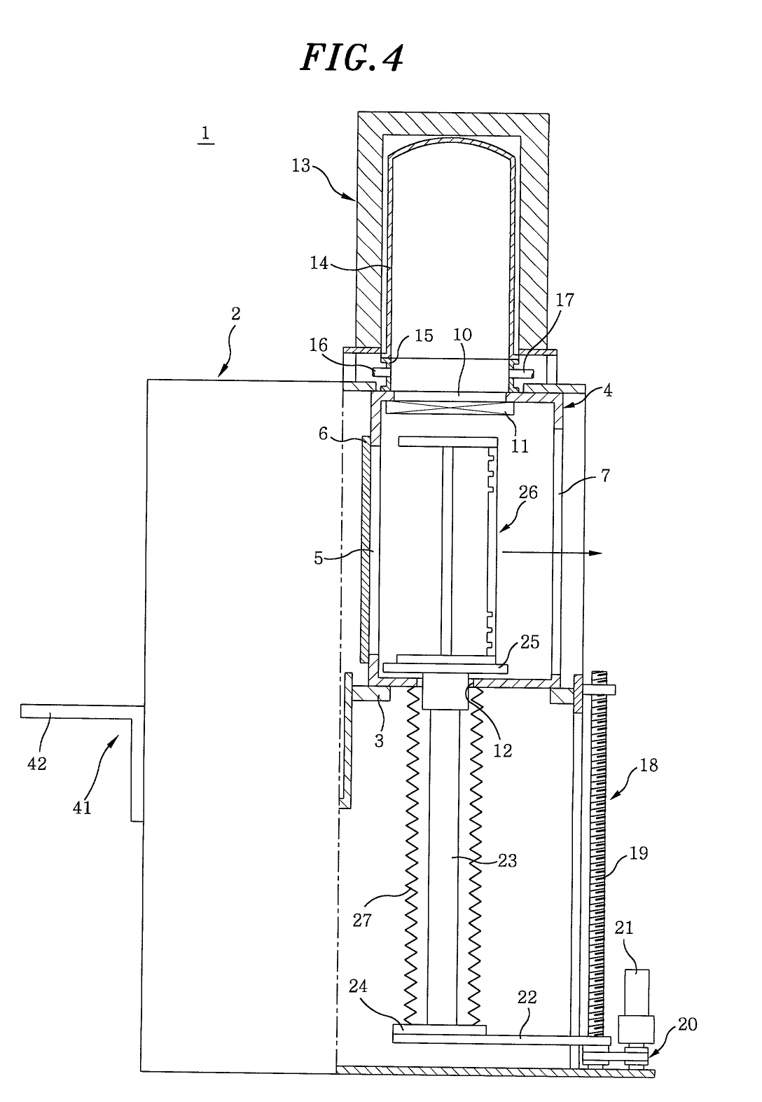

As shown in FIG. 4, the load lock state of the load lock chamber 4, in which the load lock chamber 4 is supported in the upper portion of the housing 2 by means of the fixture 3, the wafer opening 10 is closed by the gate 11, and the empty boat 26 is in the load lock chamber 4, ends up with the opening of the maintenance opening 7 by the gate 8 and then, the empty boat 26 is taken out of the load lock chamber 4 through the maintenance opening 7 for the cleaning process.

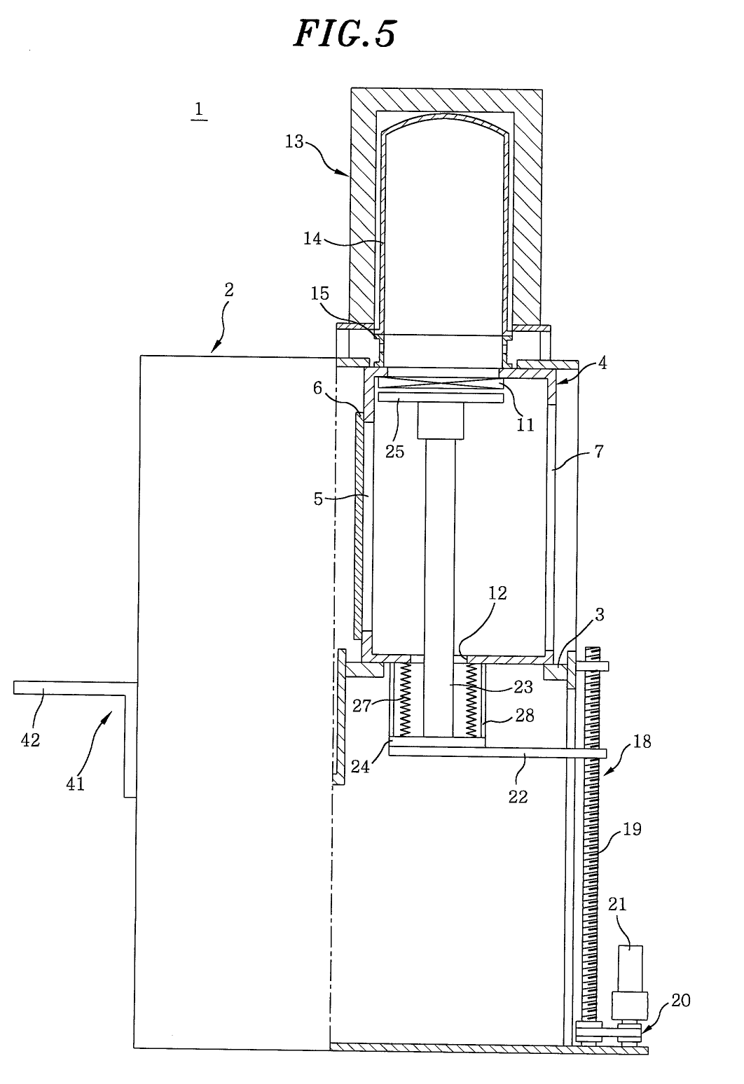

Next, the support column 23 is raised into the load lock chamber 4 by passing through the opening 12 thereof by the boat elevator 18 as shown in FIG. 5. At this time, since the boat 26 has been removed from the sealing cap 25, the sealing cap 25 is raised without having the boat 26 thereon. When the support column 23 is raised to a predetermined position, a supporting member 28 is inserted between the load lock chamber 4 and the flange 24 and then the fixture 3 fixing the load lock chamber 4 to the housing 2 is released therefrom. Due to the removal of the fixture 3, the load lock chamber 4 is now supported by the lift arm 22 of the boat elevator 18 through the supporting member 28.

Next, the gas supply line 16 and the exhaust line 17 are separated from the manifold 15. Then the lift arm 22 of the elevator 18 is lowered to a preset position by the motor 21, with a stroke of the lift arm 22 being greater than the height of the process tube 14. As the lift arm 22 is lowered to the preset position, the load lock chamber 4 supported by the lift arm 22 through the supporting member 28 is also lowered to be located in a lower position of the housing 2. At this time, since the moving stroke of the lift arm 22 is greater than the height of the process tube 14, the process tube 14 mounted on the load lock chamber 4 is wholly extracted from the heater unit 13. Then the process tube 14 taken into the upper position of the housing 2 is moved out of the housing 2 for a subsequent cleaning process of the process tube 14.

The cleaned process tube 14 is then disposed on the load lock chamber 4 and carried back into the heater unit 13 by performing the processes described above in a reverse sequence. In addition, the cleaned boat 26 is carried back into the load lock chamber 4 through the maintenance opening 7 and disposed on the sealing cap 25 rigidly attached to the support column 23.

Some of the advantages obtained by the preferred embodiment of the present invention are as followings:

1) The structure of the batch-type CVD apparatus 1 is designed such that the load lock chamber 4 can be lowered and raised with the process tube 14 disposed thereon. Therefore, the process tube 14 can be lowered along with the load lock chamber 4 and easily extracted from the housing 2. As a result, both the system efficiency rate of operation of the batch-type CVD apparatus 1 and the production yield of the semiconductor devices can be increased.

2) Since both the load lock chamber 4 and the process tube 14 can be lowered or raised together by the boat elevator 18, the boat elevator 18 can be commonly used for the maintenances of the boat 26 and the process tube 14. Accordingly, the expenditure on the maintenances and the batch-type CVD apparatus 1 and the maintenance thereof can be less costly. Further, the size of the batch-type CVD apparatus 1 can be reduced, thereby economizing the footprint thereof.

3) Since the moving stroke of the load lock chamber 4 is designed to be greater than the height of the process tube 14, the process tube 14 can be completely extracted from the heater unit 13 by lowering the load lock chamber 4. Accordingly, the maintenance of the process tube 14 can be safely carried out.

4) Since the centers of the load lock chamber 4 and the process tube 14 are designed to be substantially aligned with each other, they can be safely raised and lowered by the lift arm 22 of the elevator 18. Accordingly, the maintenance process of the process tube can be safely performed.

5) The boat elevator 18 is installed outside the housing 2 containing therein the load lock chamber 4 and the process tube 14 is supported by the support column 23 vertically attached on the lift arm 22 through the sealing cap 25 that is also used to hermetically seal the furnace mouth of the process tube 14. Further, the support column 23 is enveloped with the bellows 27 airtightly attached to the support opening 12 of the load lock chamber 4, through which the support column 23 passes. Therefore, the load lock chamber 4 and the process tube 14 are raised or lowered together while maintaining the load lock chamber 4 to be airtightly sealed. Accordingly, the elevator boat 18 can be commonly used for raising or lowering the process tube 14 and the load lock chamber 14 and the maintenance work for the boat elevator 18 can be done easily.

6) Since only the support is accommodated inside the bellows, the diameter thereof can be made small. Accordingly, the resultant force required to counteract the pressure difference developed when the load lock chamber 4 is evacuated can be reduced and thereby the sizes of the motor 21 and the transmission device 20 can be reduced.

7) Even though another guide member besides the boat elevator 18 is additionally installed, the sealing cap 25, the lift arm 22 and a guide of the load lock chamber 4 can be commonly used. Accordingly, manufacturing cost of the batch-type CVD apparatus having another guide member can be reduced.

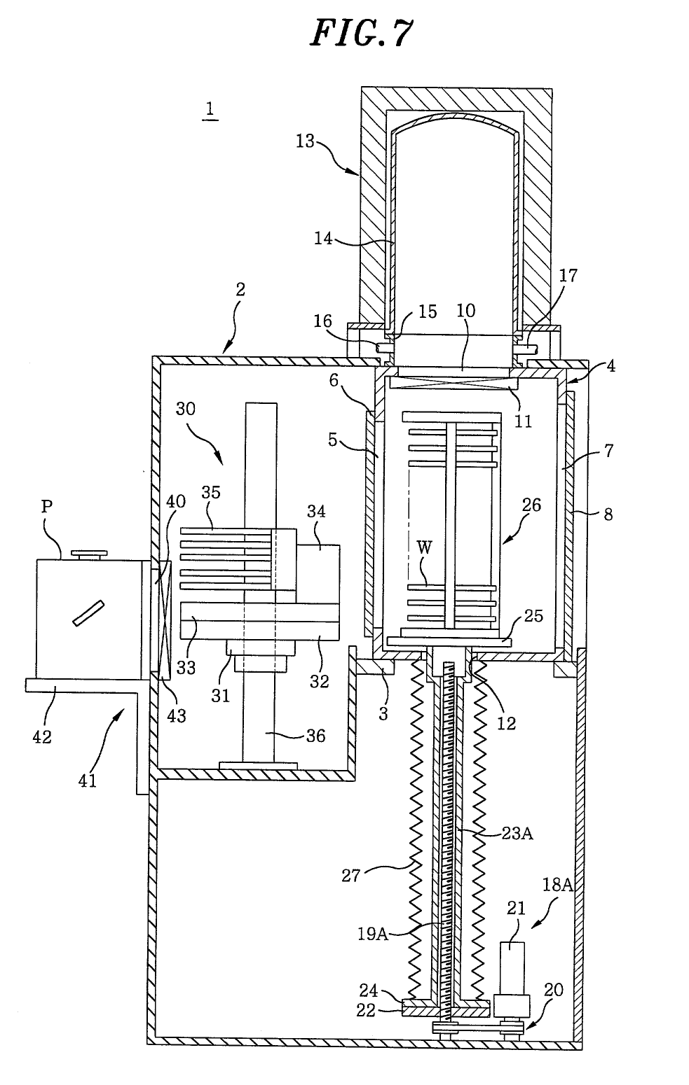

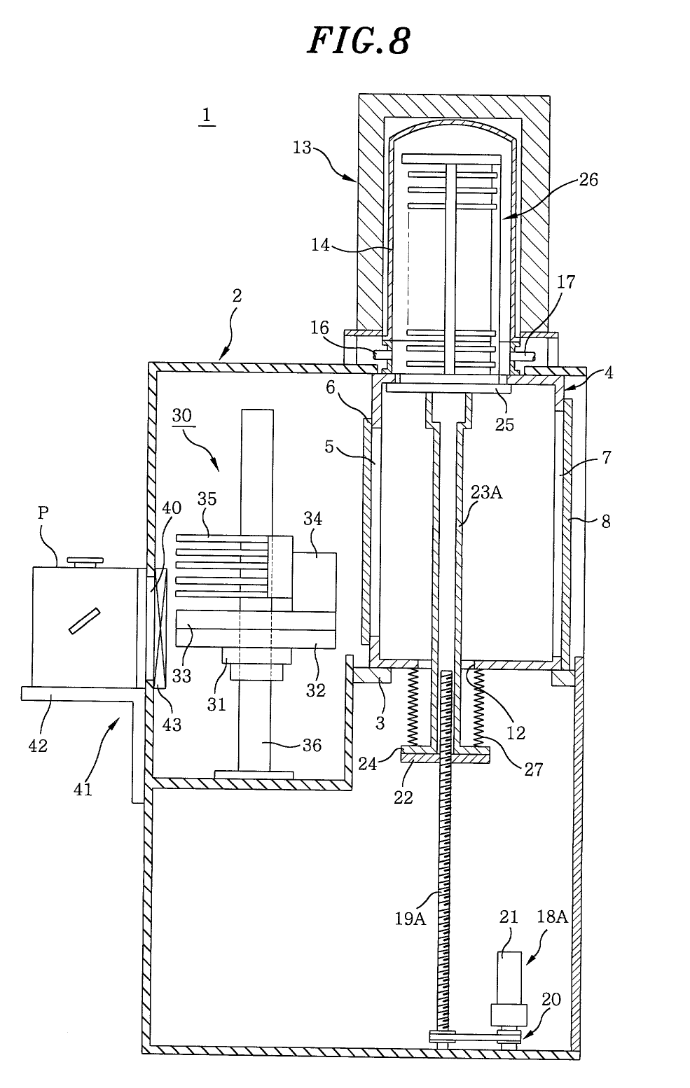

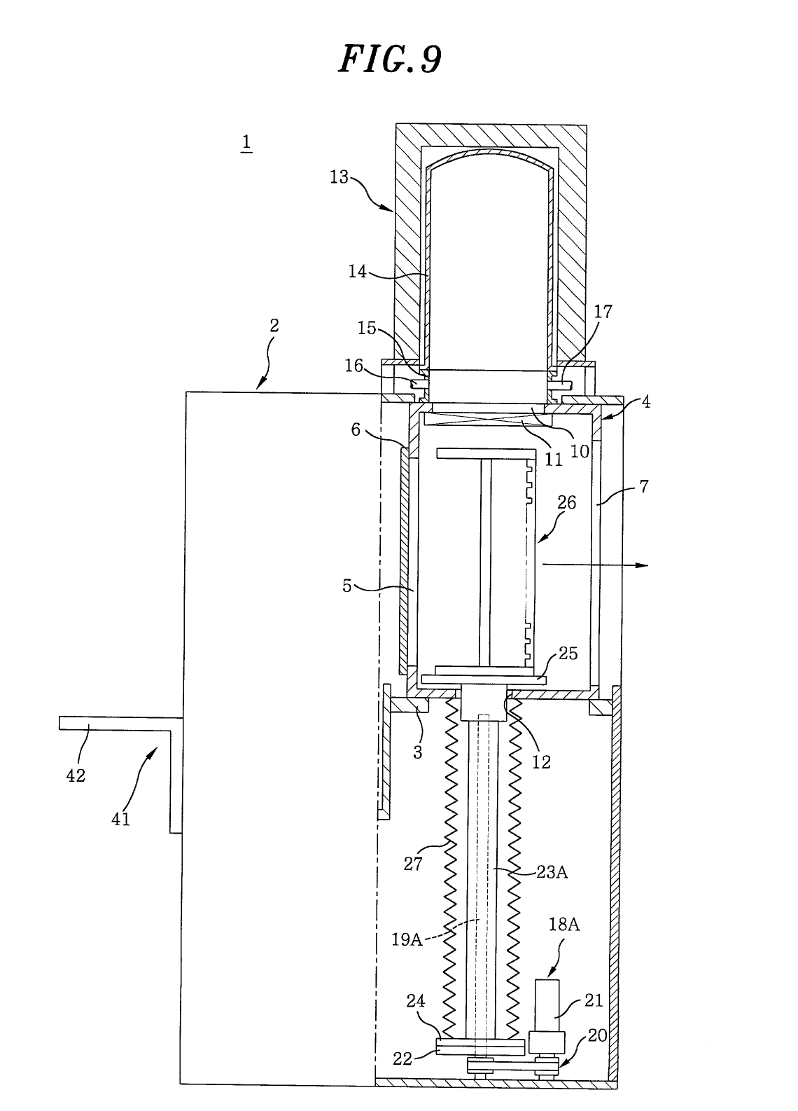

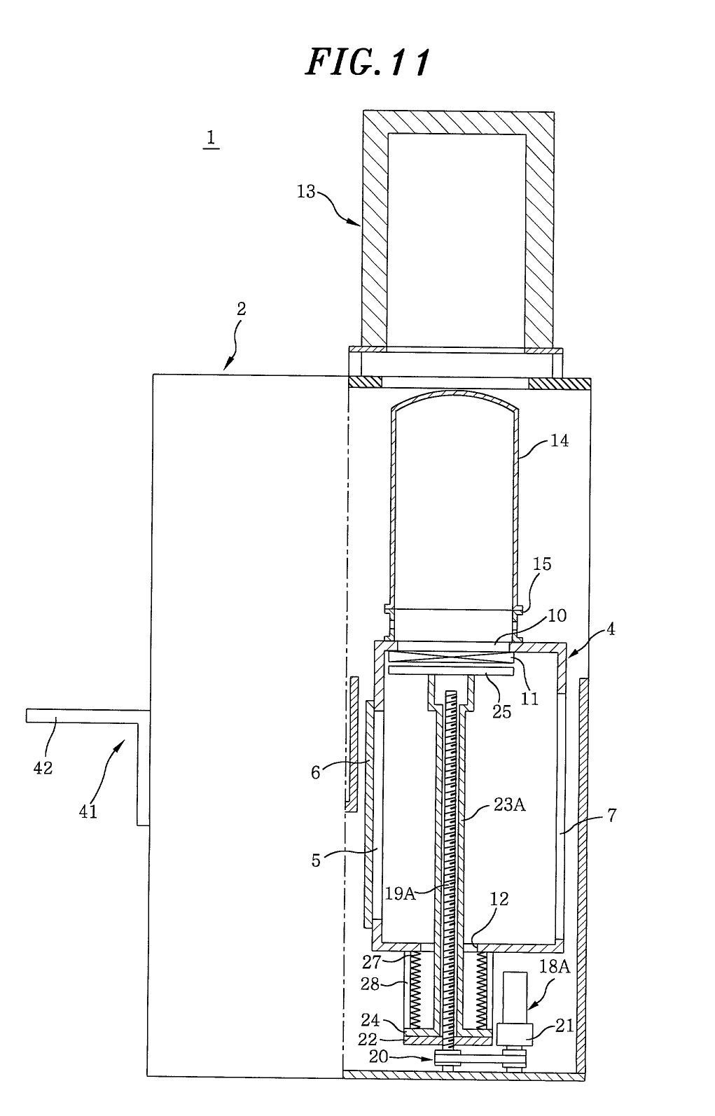

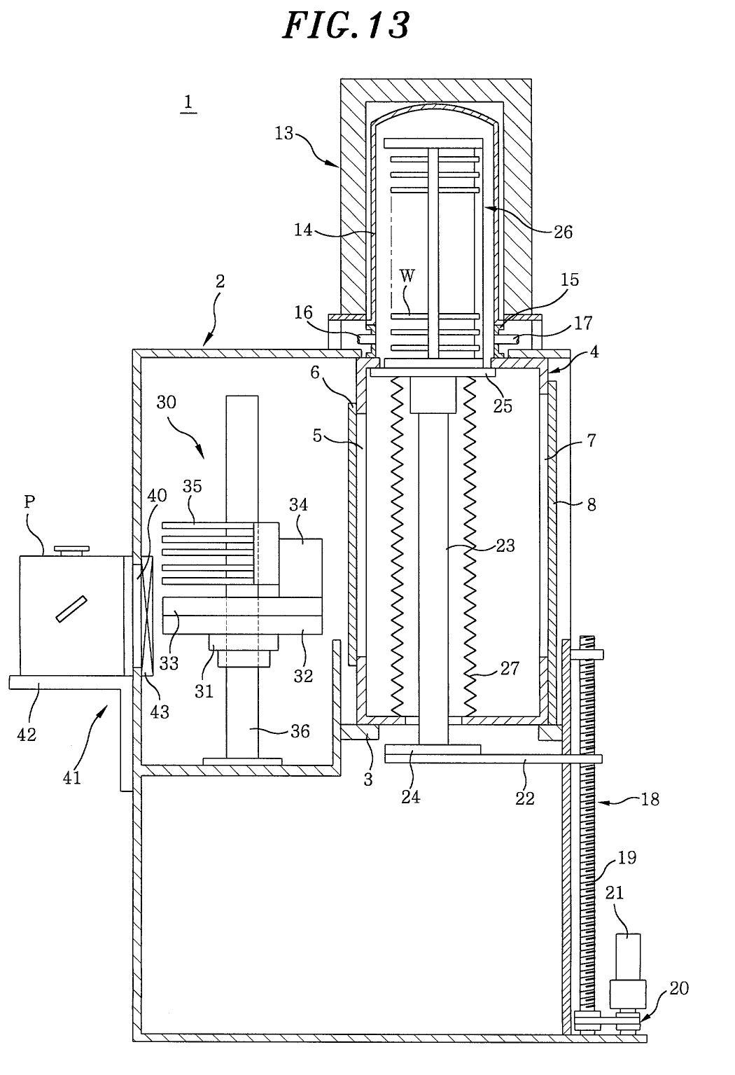

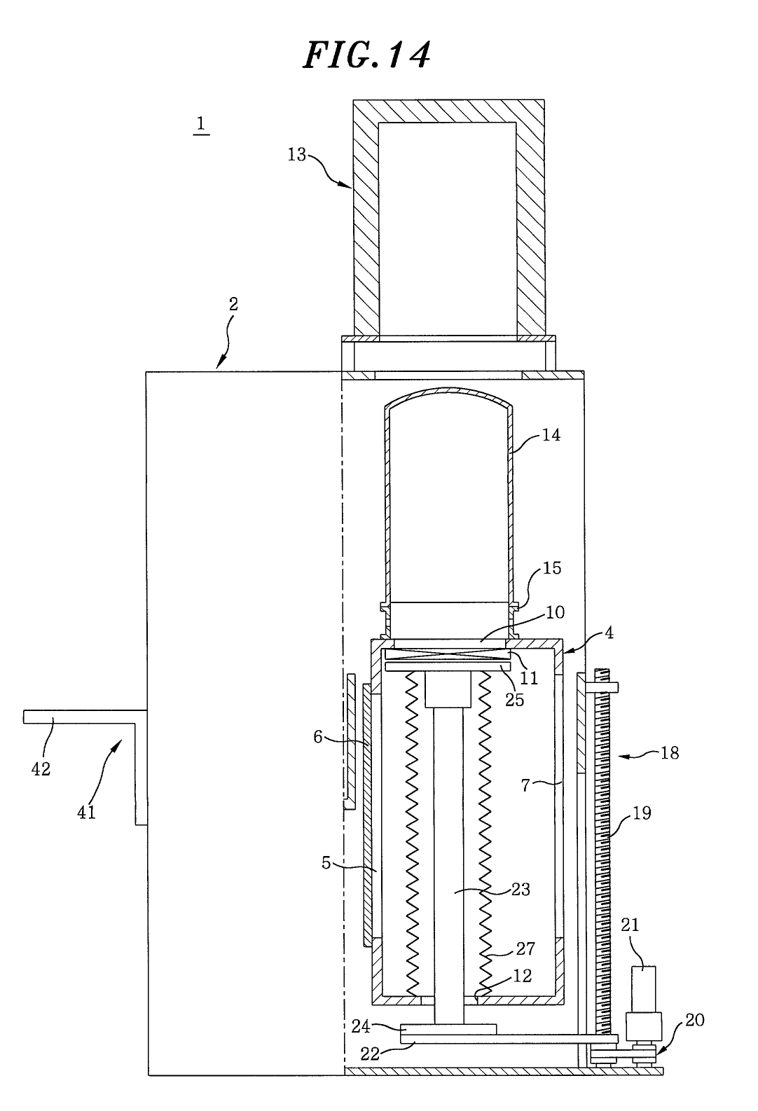

Batch-type CVD apparatuses in accordance with other preferred embodiments of the present invention are described in FIGS. 7 to 14.

The batch-type CVD apparatus 1 in accordance with a second preferred embodiment of the present invention is different from the first preferred embodiment, in that the boat elevator 18A is installed inside the housing 2 and that a feed screw 19A is concentrically threaded into a hollow of a pipe-shaped support column 23A. In addition, the motor 21 is installed such that the bottom wall of the load lock chamber 4 does not come into a contact therewith after the load lock chamber 4 is lowered to its lowest position.

The film forming process and the maintenance process of the second preferred embodiment are performed in a similar manner as in the first preferred embodiment.

That is, as shown in FIG. 7, the wafers W in the pod P are transferred to the empty boat 26 while the load lock chamber 4 containing the empty boat 26 therein maintains a fixedly mounted state at the upper portion of the housing 2.

After a predetermined number of wafers W are loaded in the boat 26, the boat 26 is raised to be loaded into the process tube 14. Since the inner space of the load lock chamber 4 has been evacuated through the exhaust line 9 before the boat 26 is loaded into the process tube 14, introduction of the oxygen and the moisture into the process tube 14 is effectively prevented.

Next, the inner space of the process tube 14 is airtightly closed, evacuated through the exhaust line 17 to a predetermined pressure and then, heated to a predetermined temperature. After that a predetermined amount of the process gas is introduced thereinto to form a layer on the wafers W under a predetermined condition.

After a predetermined period of time being elapsed, the boat 26 holding processed wafers W is lowered by the boat elevator 18A, so that the boat 26 is unloaded from the process tube 14 as shown in FIG. 7. Then the processed wafers W are transferred from the boat 26 to the empty pod P mounted on the loading port 42 of the pod opener 41 through the wafer loading/unloading opening 40 by the wafer transfer device 30.

The maintenance process of the boat 26 and the process tube 14 will now be described.

After all processed wafers W are transferred to the pod P, the load-locked state ends up with the opening of the maintenance opening 7 by the gate 8 while the load lock chamber 4 containing the boat 26 therein maintains a fixedly mounted state at the upper position of the housing 2. Next, the empty boat 26 is carried out of the load lock chamber 4 through the maintenance opening 7 for the cleaning process of the boat 26.

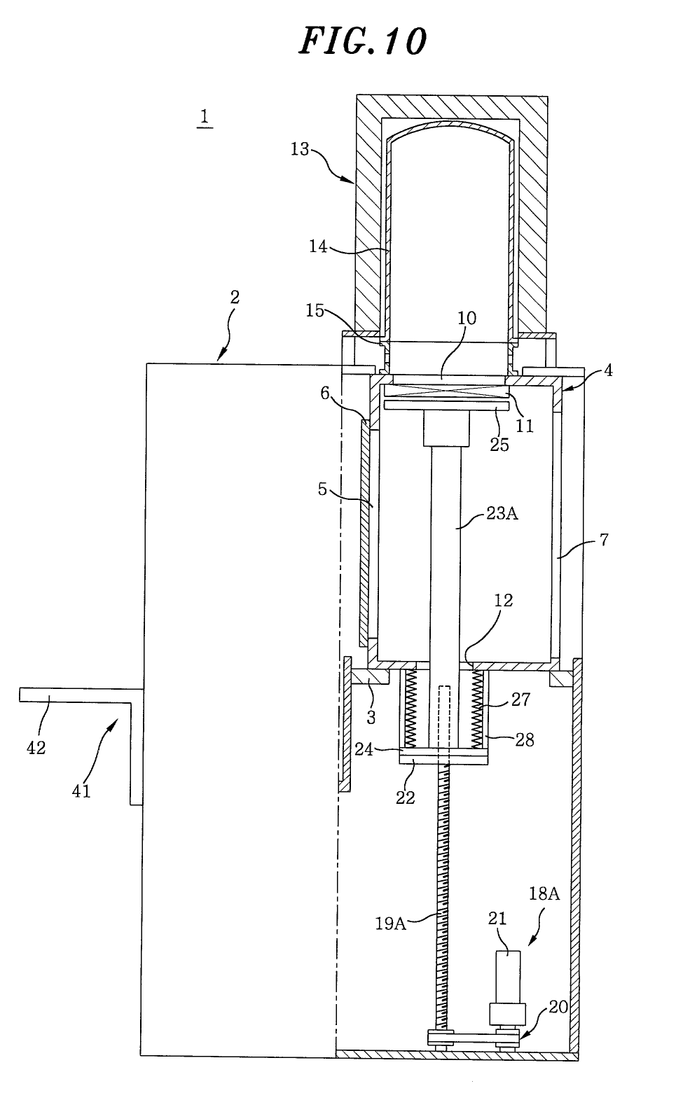

After that, the support column 23A is raised into the load lock chamber 4 by passing through the support opening 12 by the boat elevator 18A to a predetermined position as shown in FIG. 10. A supporting member 28 is inserted between the load lock chamber 4 and the flange 24 and then, the fixture 3 fixing the load lock chamber 4 to the housing 2 is released therefrom. Due to the removal of the fixture 3, the load lock chamber 4 is now supported with the lift arm 22 through the supporting member 28.

Next, the gas supply line 16 and the exhaust line 17 are separated from the manifold 15. Then the lift arm 22 of the boat elevator 18A is lowered by the moving stroke, which is greater than the height of the process tube 14. After the lift arm 22 is lowered to a predetermined position, the load lock chamber 4 supported by the lift arm 22 through the supporting member 28 is taken into an upper position of the housing 2. Then the process tube 14 is moved out of the housing 2 for a subsequent cleaning process of the process tube 14.

The cleaned process tube 14 is then disposed on the load lock chamber 4 and the processes described above are performed in a reverse sequence, so that the process tube 14 is carried back into the heater unit 13. Further, the washed boat 26 is carried into the load lock chamber 4 through the maintenance opening 7 and disposed on the sealing cap 25 rigidly attached on the support column 23A.

According to the second preferred embodiment of the present invention, since the feed screw 19A is concentrically threaded into the hollow of the support column 23A, a bending moment does not occur in the lift arm 22 or the feed screw 19A. Accordingly, the structure of the boat elevator 18A can be further down-sized and simplified.

Further, it should be noted that the preferred embodiments described above can be modified without departing from the scope of the present invention.

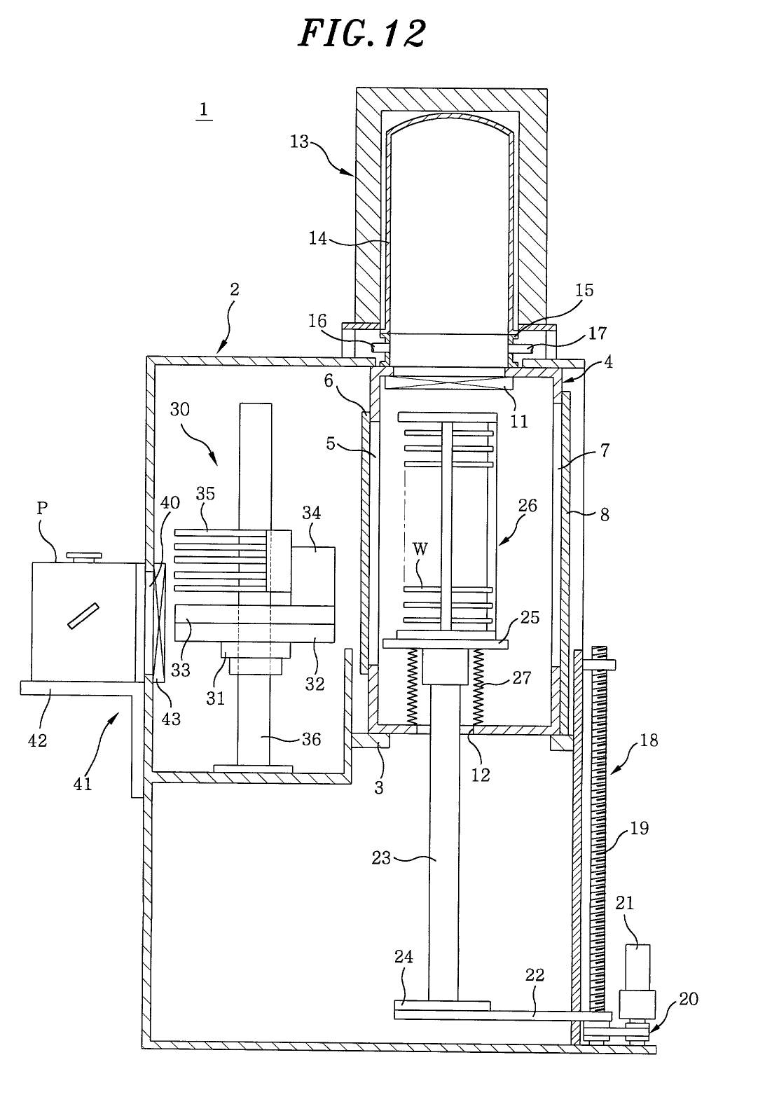

For instance, the bellows 27, which is installed between the bottom of the load lock chamber 4 and the lift arm 22 as in the first and the second preferred embodiment, can be installed between the lower surface of the sealing cap 25 and the upper surface of the bottom wall of the load lock chamber 4 as shown in FIGS. 12 to 14. This third preferred embodiment of the present invention can also provide similar effects and advantages as in the first and the second preferred embodiment.

Further, it should be noted that the batch-type CVD apparatus 1 can be of the type to be used, e.g., in forming oxidation layers or carrying out a diffusion treatment.

Furthermore, it also should be appreciated that the present invention could be applied to any other substrate processing apparatuses than the batch-type CVD apparatus described above in the preferred embodiments of the present invention.

While the invention has been shown and described with respect to the preferred embodiments, it will be understood by those skilled in the art that various changes and modifications may be made without departing from the spirit and scope of the invention as defined in the following claims.

What is claimed is:

1. A substrate processing apparatus, which comprises:
a process tube, which processes a plurality of wafers held in a boat; and
a load lock chamber accommodating therein the boat before and after the boat is loaded into and unloaded from the process tube,
wherein the load lock chamber is raised and lowered along with the process tube disposed thereon.

2. The substrate processing apparatus of claim 1, wherein a moving stroke of the load lock chamber is set to be greater than a length of the process tube.

3. The substrate processing apparatus of claim 1, a center line of the process tube is substantially aligned with a center line of the load lock chamber.

4. The substrate processing apparatus of claim 1, wherein the load lock chamber and the boat are raised and lowered by a boat elevator.

5. A substrate processing apparatus, which comprises;
a housing;
a process tube, which processes a plurality of wafers held in a boat;
a load lock chamber located in the housing and accommodating therein the boat before and after the boat is loaded into and unloaded from the process tube;
a boat elevator attached to the housing and installed outside the load lock chamber for raising and lowering a lift arm assembly;
a support column vertically disposed on the lift arm assembly and passing through an opening formed in a bottom wall of the load lock chamber;
a sealing cap, attached to an upper end of the support column, for sealing an opening of the process tube, the boat being disposed on the sealing cap; and
a bellows surrounding the support column, one end of the bellows being airtightly attached to a periphery of the opening formed in the bottom wall of the load lock chamber and the other end of the bellows being airtightly attached to the lift arm assembly.

6. The substrate processing apparatus of claim 5, wherein the support column is configured of a pipe shape and a feed screw of the boat elevator is disposed inside the support column.

7. The substrate processing apparatus of claim 6, wherein the boat elevator is provided with a motor for rotating the feed screw, a height of an upper end of the motor being lower than that of a bottom surface of the load lock chamber when the bellows is fully contracted.

8. A substrate processing apparatus, which comprises;
a housing;
a process tube, which processes a plurality of wafers held in a boat;
a load lock chamber located in the housing and accommodating therein the boat before and after the boat is loaded into and unloaded from the process tube;
a boat elevator attached to the housing and installed outside the load lock chamber for raising and lowering a lift arm assembly;
a support column vertically disposed on the lift arm assembly and passing through an opening formed in a bottom wall of the load lock chamber;
a sealing cap, attached to an upper end of the support column, for sealing an opening of the process tube, the boat being disposed on the sealing cap; and
a bellows surrounding the support column, one end of the bellows being airtightly attached to a periphery of the opening formed in the bottom wall of the load lock chamber and the other end of the bellows being airtightly attached to the sealing cap.

9. The substrate processing apparatus of claim 8, wherein the support column is configured of a pipe shape and a feed screw of the boat elevator is disposed inside the support column.

10. A method for fabricating a semiconductor device comprising the steps of;
loading a plurality of wafers into a boat;
loading the boat having therein the plurality of wafers into a process tube from a load lock chamber, the load lock chamber being capable of being raised and lowered while the process tube being disposed thereon; and
processing the plurality of wafers loaded into the process tube.

11. The method of claim 10, further comprising the steps of:
lowering the load lock chamber and the process tube while the process tube is disposed on the load lock chamber; and
taking the process tube out of the substrate processing apparatus.
